(19) United States
(12) Patent Application Publication
(10) Pub. No.: US 2023/0402819 A1
(43) Pub. Date: Dec. 14, 2023

(54) LIGHT EMITTING DEVICE AND MEASURING DEVICE

(71) Applicant: FUJIFILM BUSINESS INNOVATION CORP., Tokyo (JP)

(72) Inventor: Daisuke IGUCHI, Kanagawa (JP)

(73) Assignee: FUJIFILM BUSINESS INNOVATION CORP., Tokyo (JP)

(21) Appl. No.: 18/447,763

(22) Filed: Aug. 10, 2023

Related U.S. Application Data
(63) Continuation of application No. PCT/JP2021/027750, filed on Jul. 27, 2021.

(30) Foreign Application Priority Data
Mar. 22, 2021 (JP) 2021-047642

(51) Int. Cl. H01S 5/042; H01S 5/02315; G01S 7/484; G01S 17/10

(52) U.S. Cl. CPC H01S 5/0428; H01S 5/02315; G01S 7/484; G01S 17/10; H01S 5/423

(57) ABSTRACT

A light emitting device includes: a light emitting element; a switch element that is connected in series to one of electrodes of the light emitting element, and that drives the light emitting element; a capacitive element that is connected in parallel to the light emitting element, and that discharges a charged electric charge to the light emitting element; and a resistance element provided between the capacitive element and a power supply that charges the capacitive element on a same base.

### CROSS-REFERENCE TO RELATED APPLICATIONS

This is a continuation of International Application No. PCT/JP2021/027750, filed on Jul. 27, 2021 and claims priority from Japanese Patent Application No. 2021-047642 filed on Mar. 22, 2021.

### BACKGROUND

### (i) Technical Field

The present disclosure relates to a light emitting device and a measuring device.

### (ii) Related Art

Japanese Unexamined Patent Application Publication No. 2019-219400 discloses a method of measuring a depth, the method being non-reactive to broken light caused by internal reflection and including: emitting light to a scene by a light source; performing broken light measurement by controlling a first electric charge storage unit of a pixel so as to collect electric charges based on light to which the pixel is exposed during a first period in which the pixel is exposed to broken light, but is not exposed to return light from an object within the field of view of the pixel; removing contribution by the broken light from one or more measurements affected by the broken light based on the broken light measurement; and determining the depth based on the one or more measurements with the contribution by the broken light removed.

Japanese Unexamined Patent Application Publication No. 2019-028039 discloses a distance measuring device including: a light projector that projects light to an object; a light receiver that receives light reflected or scattered by the object; a scanner that scans a scanning area with the light projected from the light projector; and a distance measuring unit that measures the distance to the object by measuring the time period from light projection by the light projector to light receiving by the light receiver, and it is determined whether a measurement value of a first division area can be regarded as a measurement result of the first division area based on the measurement value of the first division area, measured by the measuring unit, and the measurement value of a second division area, measured earlier than the measurement value of the first division area during a one scan, and when the measurement value is determined to be regarded as the measurement result of the first division area, the measurement value of the first division area is output as the distance to the object in the first division area, the one scan being defined as scanning from a scan start of one of a plurality of division areas to a scan end of all the division areas, into which the scanning area is divided.

Japanese Unexamined Patent Application Publication No. 2017-15448 discloses a light flight distance measurement device including: a first light source that emits first light to a first light emission space; a light receiver that has a plurality of pixels and receives light by the pixels; a range image acquisition unit that, for each of the pixels, acquires a range image indicating the distance from the distance measurement device to an object by the light receiver receiving light including first reflection light in which the first light is reflected by the surface of the object in a light emission period in which the first light is repeatedly emitted from the first light source; a brightness value image acquisition unit that acquires a brightness value image indicating a brightness value of each of the pixels by the light receiver receiving light including second reflection light in which second light is reflected by the surface of the object in a non-light emission period in which the first light is not repeatedly emitted from the first light source, the second light being emitted from a second light source to a second light emission space including at least part of the first light emission space along an optical axis different from that of the first light; and a multi-path detector that detects an area where a multi-path occurs using the range image and the brightness value image.

Japanese Unexamined Patent Application Publication No. 2007-333592 discloses a distance measuring device including a light emitter that emits exploration light, and a light receiver that receives reflection light of the exploration light and being configured to measure the distance to an object which has reflected the exploration light, based on the reflection light received by the light receiver. In the distance measuring device, the light receiver is installed at a position away from a strong scattering region which is centered on the light emitter and in which the intensity of scattered light has a magnitude exceeding the noise level of the light receiver, the scattered light being produced by the exploration light passing through drops of water having a diameter larger than the wavelength of the exploration light or the exploration light being reflected by the drops of water, and the distance measuring device is provided with a light shielding unit that shields part of the scattered light, the part being convergence scattered light that converges in a specific direction and scattered light to be incident on the light receiver at an incidence angle greater than that of the convergence scattered light.

### SUMMARY

Aspects of non-limiting embodiments of the present disclosure relate to providing a light emitting device and a measuring device that, when a light emitting element is caused to emit light by discharging to the light emitting element, an electric charge stored in a capacitive element connected in parallel to the light emitting element, are capable of setting a charge time for the capacitive element.

Aspects of certain non-limiting embodiments of the present disclosure address the above advantages and/or other advantages not described above. However, aspects of the non-limiting embodiments are not required to address the advantages described above, and aspects of the non-limiting embodiments of the present disclosure may not address advantages described above.

According to an aspect of the present disclosure, there is provided a light emitting device including: a light emitting element; a switch element that is connected in series to one of electrodes of the light emitting element, and that drives the light emitting element; a capacitive element that is connected in parallel to the light emitting element, and that discharges a charged electric charge to the light emitting element; and a resistance element provided between the capacitive element and a power supply that charges the capacitive element on a same base.

### BRIEF DESCRIPTION OF THE DRAWINGS

Exemplary embodiments of the present disclosure will be described in detail based on the following figures, wherein:

FIG. 1 is a graph for illustrating relaxation oscillation;

FIG. 2 is a schematic configuration view illustrating the configuration of a measuring device;

FIG. 3 is a block diagram illustrating the configuration of an electric system of the measuring device;

FIG. 4 is a plan view of a light source;

FIG. 5 is a circuit diagram of the measuring device;

FIG. 6A is a plan view of a heat dissipation base;

FIG. 6B is a cross-sectional view taken along VIB-VIB of FIG. 6A;

FIG. 6C is a cross-sectional view taken along VIC-VIC of FIG. 6A;

FIG. 7 is a plan view of an electrode on a rear surface side of the heat dissipation base; and

FIG. 8 is a view for illustrating signal wires in a configuration including multiple pairs of a light source and an FET device.

### DETAILED DESCRIPTION

Hereinafter, an example an exemplary embodiment according to the disclosed technique will be described in detail with reference to the drawings.

Measuring devices that measure the three-dimensional shape of a to-be-measured object includes a measuring device that measures the three-dimensional shape of a to-be-measured object based on flight time of light, so-called a time of flight (ToF) method. In the ToF method, the time period from a timing when light is emitted by a light source of the measuring device to a timing when radiated light is reflected by a to-be-measured object and received by a three-dimensional sensor (hereinafter denoted as a 3D sensor) of the measuring device is measured, thus the three-dimensional shape is identified by measuring the distance to the to-be-measured object. Note that an object for which the three-dimensional shape is measured is referred to as a to-be-measured object. The to-be-measured object is an example of an object to be detected. In addition, measuring a distance may be referred to as ranging, and measuring a three-dimensional shape may be referred to as three-dimensional measurement, 3D measurement or 3D sensing.

The ToF method includes a direct method and a phase difference method (also referred to as an indirect method). The direct method is a method in which a pulsed light that is caused to emit only for an extremely short time is radiated to a to-be-measured object, and the time until the light returns is measured. The phase difference method is a method in which a pulsed light is periodically flashed, and the time delay when a plurality of beams of pulsed light shuttle between a light source and a to-be-measured object is detected as the phase difference.

Such a measuring device is installed in e.g., a mobile information processing device, and utilized for face recognition of a user who tries to access it. Conventionally, a method of authenticating a user by password, fingerprint, or iris has been used for mobile information processing devices. In recent years, authentication methods having higher security are demanded. Thus, mobile information processing devices are equipped with a measuring device that measures a three-dimensional shape. Specifically, the three-dimensional image of the face of a user who has made access is obtained, whether access is allowed is identified, and only when the user is authenticated and allowed to access the device (the mobile information processing device), the device is allowed to be used.

Such a measuring device is also used when the three-dimensional shape of a to-be-measured object is continuously measured, for example, in Augmented Reality (AR).

The configuration, function, and method explained in the exemplary embodiment described below are also applicable to not only face recognition and augmented reality, but also measurement of the three-dimensional shapes of other to-be-measured objects.

In a short distance where the distance to a to-be-measured object is less than approximately 5 m, the phase difference method is mostly used. However, with the phase difference method, in order to increase the measurement range to a long distance, the drive frequency of the light source has to be decreased, and the accuracy of measurement is reduced. Thus, when the distance to a to-be-measured object is long, the direct method is mostly used. In this exemplary embodiment, a description will be given when a three-dimensional shape is measured by the direct method.

In the direct method, it is common that a single photon avalanche diode (SPAD) device is used in the 3D sensor, and the round-trip time of an optical pulse is directly measured by the SPAD device. When detecting one photon, the SPAD device generates electrons increasingly. The capacitive element of the 3D sensor is charged with the generated electrons. When the rise time for light emission is delayed after the drive current is supplied to cause the light source to emit light, even with the same distance to a to-be-measured object, the response timing of the SPAD device changes depending on the amount of reflected light, thus a measurement error occurs. Therefore, it is necessary to advance the rise time for light emission after the drive current is supplied to the light source.

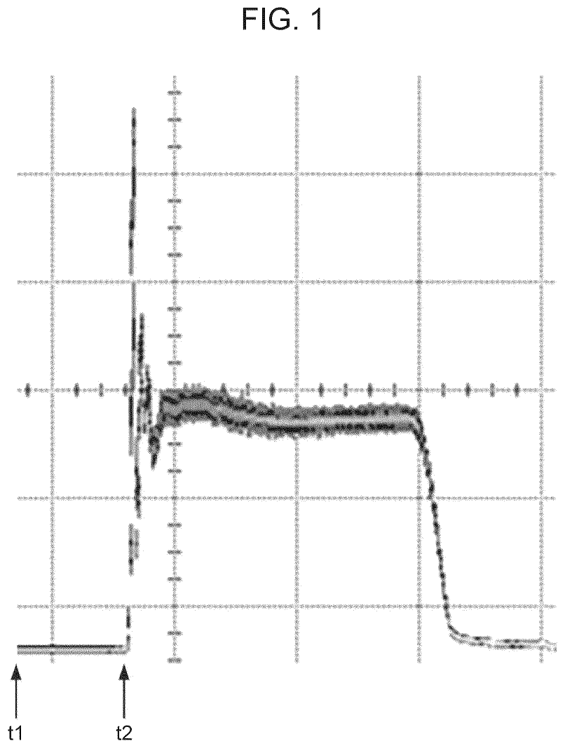

When the light source is driven by a current, a delay and vibration with several GHz occur in the time response waveform of light due to the phase difference in interaction between light and carrier. This is called relaxation oscillation. In FIG. 1, an example of a waveform of relaxation oscillation is illustrated. The horizontal axis in FIG. 1 represents time, and the vertical axis represents optical output. As illustrated in FIG. 1, an operation of rising the optical output up to several times the wave height of a steady-state value in a short time of several 10 ps since the drive current is supplied at t1 until light emission is started at t2 is called gain switching. The sensitivity and the accuracy of distance measurement by the direct method are determined by the peak power of optical output and the rise time.

For ranging by the direct method, response of the optical output after the tip portion (t2) of the rise of light emission is unnecessary, and waste of energy. In other words, it is sufficient that the drive current to be supplied to the light source have enough magnitude and pulse width for rise of the optical output in the gain switching operation. Thus, the drive current is required to be a high current with a pulse width of several 100 ps.

In the direct method, infrared pulsed light with several 10 W is necessary to range a distance exceeding 10 m in outdoors where strong daylight, such as 100 klx light, shines. For example, in order to generate pulsed light with a pulse width of several 100 ps by a high current of 10 A, the inductance of a current path including the drive circuit for the light source has to be minimized. At the same time, in order to perform fast ranging with high accuracy, high-current pulsed light needs to be emitted with high frequency, which arises a problem of heat generation of light emitting elements. Thus, heat dissipation is assisted by mounting a light source on a heat dissipation base (sub mount) composed of a high thermal conductivity material such as AlN (aluminum nitride). However, the mounting on the heat dissipation base increases the above-mentioned inductance of the current path, thus causes pulse characteristics to deteriorate. Like this, in the light source for the direct method, achieving both the drive of a high speed large current and thermal characteristics is a great challenge.

When the light source mounted on the heat dissipation base on a wiring substrate is driven by a driver provided outside the heat dissipation base, rise of light emission is delayed because the inductance of the current path is large. Normally, the driver includes an input circuit, a control circuit, and an output circuit for high-speed pulse, thus occupies a large area. Therefore, it is difficult to directly mount the driver on the heat dissipation base.

In the final stage of the output circuit, a switch element such as an FET device is normally driven by an open drain, and an FET device such as GaN (gallium nitride) may be a small one which is approximately 1 mm square as a single body.

Thus, in this exemplary embodiment, a configuration is adopted in which the FET device in the final stage of the output circuit is mounted on the heat dissipation base, and driven by a signal generating circuit on the wiring substrate.

In order to drive a light source using the direct method by a drive current with a sufficiently short pulse, so-called resonant capacitive discharge drive may be used. Specifically, a light emitting element and the FET device of the driver are connected in series, whereas condensers are connected in parallel with respect to the ground reference so that when the FET device is turned ON, the light emitting element is driven by the discharge current of a capacitor charged by the power supply voltage, and a high current pulse with an extremely short time is obtained according to resonance conditions for the inductance of a current loop of the capacitor, the light emitting element, the FET device, and the capacitance of the capacitor. In this exemplary embodiment, a configuration is adopted in which the power supply potential side of the capacitors is connected to the power supply via a resistance element, and the capacitors are recharged with a time constant which is determined by the capacitance values of the capacitors and the resistance value of the resistance element, and the details will be described below.

(Measuring Device 1)

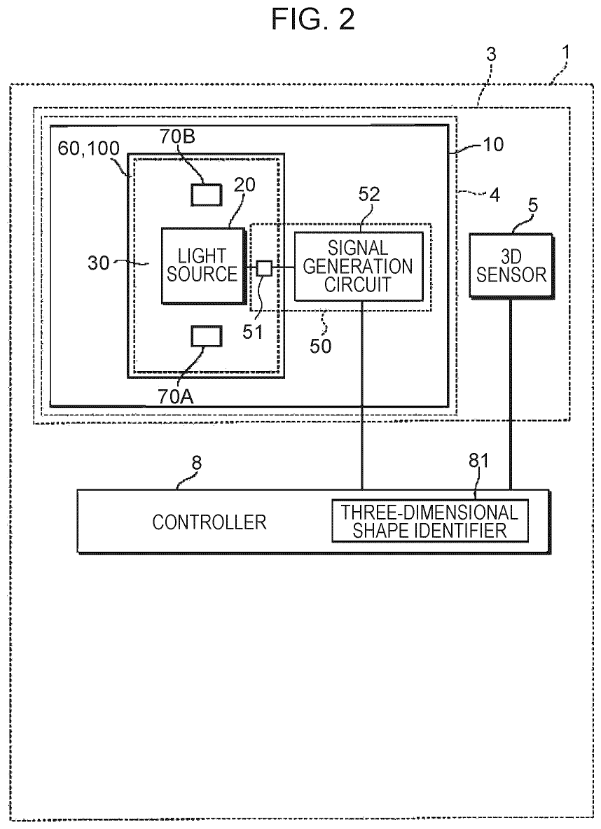

FIG. 2 is a block diagram illustrating an example of a configuration of a measuring device 1 that measures a three-dimensional shape.

The measuring device 1 includes an optical device 3 and a controller 8. The controller 8 controls the optical device 3. The controller 8 includes a three-dimensional shape identifier 81 that identifies the three-dimensional shape of a to-be-measured object.

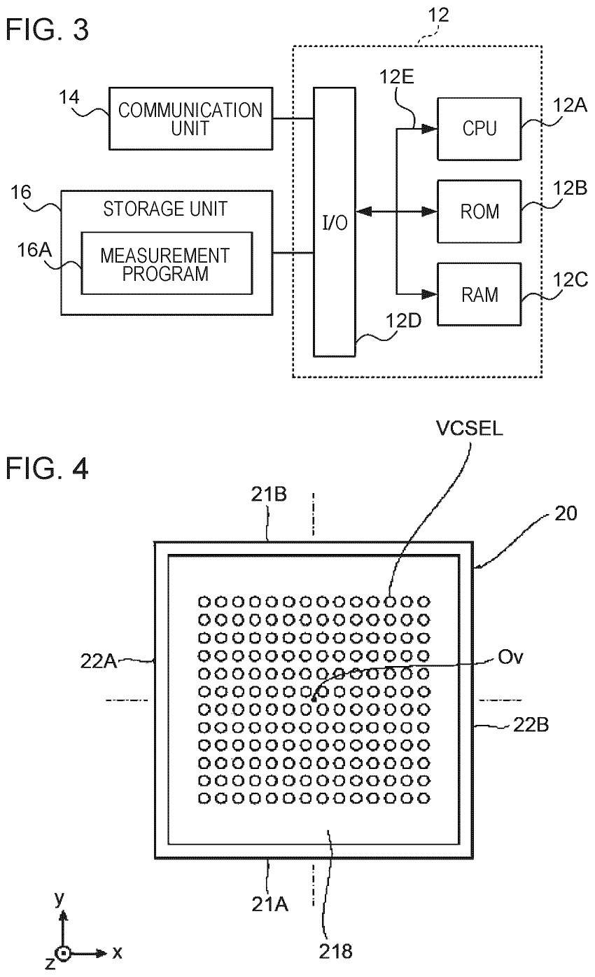

FIG. 3 is a block diagram illustrating the hardware configuration of the controller 8. As illustrated in FIG. 3, the controller 8 includes a controller 12. The controller 12 includes a central processing unit (CPU) 12A, a read only memory (ROM) 12B, a random access memory (RAM) 12C, and an input and output interface (I/O) 12D. The CPU 12A, the ROM 12B, the RAM 12C, and the I/O 12D are connected to each other via a system bus 12E. The system bus 12E includes a control bus, an address bus, and a data bus.

In addition, the I/O 12D is connected to a communication unit 14 and a storage unit 16.

The communication unit 14 is an interface to perform data communication with an external device.

The storage unit 16 is comprised of a non-volatile rewritable memory such as a flash ROM, and stores a measurement program 16A that measures the three-dimensional shape of a to-be-measured object by the direct method. The three-dimensional shape identifier 81 is implemented by the CPU 12A reading into the RAM 12C and executing the measurement program 16A stored in the storage unit 16, and the three-dimensional shape of a to-be-measured object is identified. Note that the three-dimensional shape identifier 81 is an example of a measurer.

The optical device 3 includes a light emitting device 4 and a 3D sensor 5. The light emitting device 4 includes a wiring substrate 10, a heat radiation base 100, a light source 20, a light diffusion member 30, a driver 50, a retainer 60, and capacitors 70A, 70B. The heat dissipation base 100 is an example of a base. The light source 20 is an example of a light emitting element. The 3D sensor 5 is an example of a light receiving element. The capacitors 70A, 70B are an example of a capacitive element.

The heat dissipation base 100 and the driver 50 of the light emitting device 4 are provided on the front surface of the wiring substrate 10. Note that the 3D sensor 5 is not provided on the front surface of the wiring substrate 10 in FIG. 2, but may be provided on the front surface of the wiring substrate 10.

The light source 20, the capacitors 70A, 70B and the retainer 60 are provided on the front surface of the heat dissipation base 100. The light diffusion member 30 is provided on the retainer 60. Here, the external shape of the heat dissipation base 100 and the external shape of the light diffusion member 30 are the same. Here, the front surface refers to the front side of the paper surface of FIG. 2. More specifically, in the wiring substrate 10, the face provided with the heat dissipation base 100 is referred to as the front surface, front side, or front surface side.

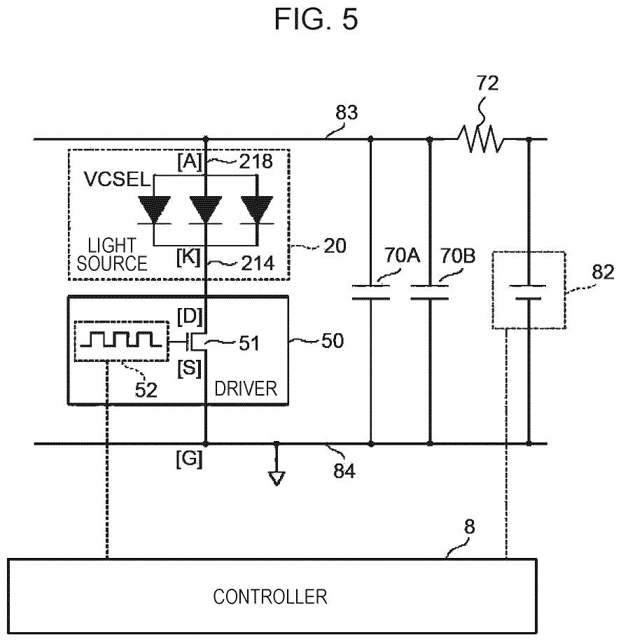

The light source 20 is constructed as a light emitting element array in which a plurality of light emitting elements are two-dimensionally provided (see FIG. 4 described below). In this exemplary embodiment, a case has been described in which the light source 20 is a light emitting element array including a plurality of light emitting elements; however, the light source 20 may be configured to include only one light emitting element. In this exemplary embodiment, a light emitting element is a vertical cavity surface emitting laser element VCSEL (Vertical Cavity Surface Emitting Laser) as an example. Hereinafter, a description will be given assuming that the light emitting element is a vertical cavity surface emitting laser element VCSEL. Hereinafter, a vertical cavity surface emitting laser element VCSEL is denoted as a VCSEL. Since the light source 20 is provided on the front surface of the heat dissipation base 100, the light source 20 emits light perpendicularly to the front surface of the heat dissipation base 100 in a direction away from the heat dissipation base 100. In other words, the light emitting element array is a surface emitting laser element array. Note that in the light source 20 in which a plurality of light emitting elements are arranged two-dimensionally, the surface from which light is emitted may be referred to as an emission surface.

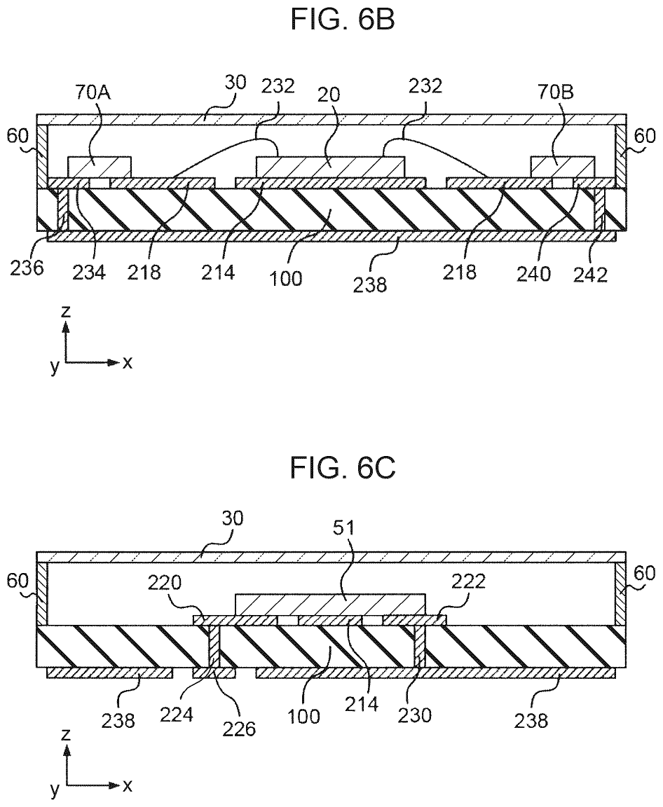

The light diffusion member 30 receives incident light emitted by the light source 20. The light diffusion member 30 diffuses and emits the incident light. The light diffusion member 30 is provided to cover the light source 20 and the capacitors 70A, 70B. Specifically, the light diffusion member 30 is provided by the retainer 60 away from the light source 20 and the capacitors 70A, 70B provided on the heat dissipation base 100 by a predetermined distance, the retainer 60 being provided on the front surface of the heat dissipation base 100 (see FIG. 6B and FIG. 6C described below). The light emitted by the light source 20 is diffused by the light diffusion member 30, and is radiated to a to-be-measured object. That is, the light emitted by the light source 20 is diffused by the light diffusion member 30, and radiated to a wider range, as compared to when the light diffusion member 30 is not provided.

The 3D sensor 5 includes a plurality of light receiving elements, for example, 640×480 light receiving elements, and outputs a signal corresponding to the time period from a timing when light is emitted by the light source 20 to a timing when the light is received by the 3D sensor 5.

For example, the light receiving elements of the 3D sensor 5 each receive pulsed reflected light (hereinafter referred to as a received light pulse) from a to-be-measured object for an emitted light pulse from the light source 20, and store an electric charge corresponding to the time until the light is received for each light receiving element. The 3D sensor 5 is constructed as a device having a CMOS structure in which each light receiving element includes two gates and charge storage units corresponding to them. Then photoelectrons generated by applying a pulse to the two gates alternately are quickly transferred to one of the two charge storage units. An electric charge corresponding to the time difference between an emitted light pulse and a received light pulse is stored in the two charge storage units. The 3D sensor 5 then outputs, as a signal, a digital value corresponding to the time difference between an emitted light pulse and a received light pulse through an AD converter for each of the light receiving elements. In other words, the 3D sensor 5 outputs a signal corresponding to the time period from a timing when light is emitted by the light source 20 to a timing when the light is received by the 3D sensor 5. That is, the distance to a to-be-measured object, in other words, a signal corresponding to the three-dimensional shape of the to-be-measured object is obtained from the 3D sensor 5. Note that the AD converter may be included in the 3D sensor 5, or may be provided outside the 3D sensor 5.

As described above, the measuring device 1 diffuses and radiates the light emitted by the light source 20 to a to-be-measured object, and receives light reflected from the to-be-measured object by the 3D sensor 5. In this manner, the measuring device 1 measures the three-dimensional shape of a to-be-measured object.

(Configuration of Light Source 20)

FIG. 4 is a plan view of the light source 20. The light source 20 is constituted by arranging a plurality of VCSELs in a two-dimensional array form. In other words, the light source 20 is constituted as a light emitting element array in which the light emitting elements are VCSELs. Let x direction be the right direction of the paper surface, and y direction be the left direction of the paper surface.

Let z direction be the direction perpendicular to the x direction and the y direction. Note that the front surface of the light source 20 refers to the front side of the paper surface, that is, the surface on +z direction side, and the rear surface of the light source 20 refers to the rear side of the paper surface, that is, the surface on −z direction side. The plan view of the light source 20 is the view when the light source 20 is seen from the front surface side.

As a further description, in the light source 20, the face provided with an epitaxial layer which functions as a light emitting layer is referred to as the front surface, front side, or front surface side of the light source 20.

A VCSEL is a light emitting element that has an active region serving as a light emitting region between a lower multilayer reflector and an upper multilayer reflector laminated on a semiconductor substrate, and that emits a laser beam in a direction perpendicular to the front surface. The VCSELs are easily arranged in a two-dimensional array, as compared to when an edge emitting laser is used. The number of VCSELs included in the light source 20 is 100 to 1000 as an example. Note that a plurality of VCSELs are connected to each other in parallel, and driven in parallel. The aforementioned number of VCSELs is an example, and may be set according to the measurement distance and the irradiation range.

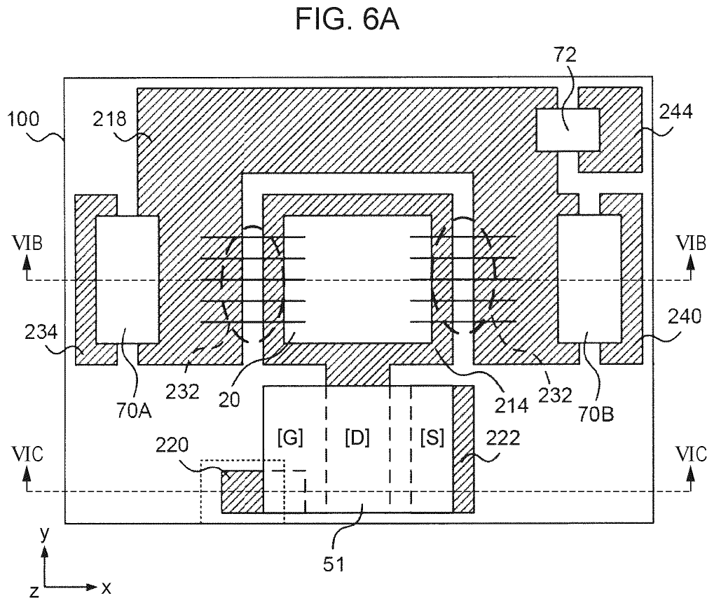

The front surface of the light source 20 is provided with an anode electrode 218 (see FIG. 5) which is common to the plurality of VCSELs. The rear surface of the light source 20 is provided with a cathode electrode 214 (see FIG. 5). In short, the plurality of VCSELs are connected in parallel. Light with high intensity is emitted by connecting the plurality of VCSELs in parallel and driving them, as compared to when VCSELs are driven individually.

Here, the shape (referred to as the planar shape, and the same applies hereinafter) of the light source 20 as seen from the front surface side is assumed to be a rectangle. Let lateral face 21A denote the lateral face on −y direction side, lateral face 21B denote the lateral face on +y direction side, lateral face 22A denote the lateral face on −x direction side, and lateral face 22B denote the lateral face on +x direction side. The lateral face 21A and the lateral face 21B are opposed. The lateral face 22A and the lateral face 22B each connect the lateral face 21A and the lateral face 21B, and are opposed.

Let center Ov be the center of the planar shape of the light source 20, that is, the center thereof in x direction and y direction.

(Driver 50 and Capacitors 70A, 70B)

When the light source 20 is desired to be driven faster, low-side drive should be performed. The low-side drive refers to a configuration in which a drive element such as a MOS transistor is located downstream of a current path with respect to an object to be driven, such as a VCSEL. Conversely, high-side drive refers to a configuration in which a drive element is located upstream.

FIG. 5 is a diagram illustrating an example of an equivalent circuit when the light source 20 is driven by the low-side drive. In FIG. 5, the VCSELs of the light source 20, the driver 50, the capacitors 70A, 70B, a resistance element 72, and a power supply 82 are illustrated. Note that the power supply 82 is provided in the controller 8 illustrated in FIG. 2. The power supply 82 generates a DC voltage having a power supply potential on +side and a reference potential on-side. The power supply potential is supplied to a power supply line 83, and the reference potential is supplied to a reference line 84. Note that the reference potential may be referred to as the ground potential (may be denoted as GND, and it is denoted as [G] in FIG. 5).

As described above, the light source 20 is constructed by connecting a plurality of VCSELs in parallel. The anode electrode 218 (see FIG. 4, denoted as [A] in FIG. 5) of the VCSEL is connected to the power source line 83.

The driver 50 includes an FET device 51, and a signal generating circuit 52 that turns ON and OFF the FET device 51. The drain (denoted as [D] in FIG. 5) of the FET device 51 is connected to the cathode electrode 214 (see FIG. 4, denoted as [K] in FIG. 5) of the VCSEL. The FET device 51 is an example of a switch element.

As the FET device 51, for example, an FET device composed of GaN (gallium nitride) is used; however, without being limited to this, an FET device composed of another material such as silicon may be used.

The source (denoted as [S] in FIG. 5.) of the FET device 51 is connected to the reference line 84. The gate of the FET device 51 is connected to the signal generating circuit 52. In short, the VCSEL and the FET device 51 of the driver 50 are connected in series between the power source line 83 and the reference line 84. The signal generating circuit 52 generates an “H level” signal that sets the FET device 51 to an ON state, and an “L level” signal that sets the FET device 51 to an OFF state by the control of the controller 8.

The capacitors 70A, 70B each have one terminal connected to the power source line 83, and the other terminal connected to the reference line 84. Here, when the capacitors 70 are plural in number, the plurality of capacitors 70 are connected in parallel. In FIG. 5, the capacitors 70 are two capacitors 70A, 70B. Each capacitor 70 is, for example, an electrolytic capacitor or a ceramic capacitor.

One terminals of the capacitors 70A, 70B are connected to one terminal of the resistance element 72. The other terminal of the resistance element 72 is connected to +side of the power supply 82.

In this manner, the capacitors 70A, 70B are connected in parallel to the light source and charged electric charge is discharged to the light source 20. In addition, the resistance element 72 is provided between the capacitors 70A, 70B and the power supply 82 that charges the capacitors 70A, 70B. Note that the capacitances of the capacitors 70A, 70B are relatively low to an extent such that, for example, 63.2% of the electric charge stored during an OFF state of the FET device 51 is discharged during an ON state of the FET device 51.

Next, the driving method which is the low-side drive for the light source 20 will be described.

First, the signal generated by the signal generating circuit 52 in the driver 50 is assumed to be “L level”. In this case, the FET device 51 is in an OFF state. Specifically, no current flows between the source ([S] in FIG. 5) and the drain ([D] in FIG. 5) of the FET device 51. Thus, no current flows through the VCSELs which are connected in series to the FET device 51. That is, the VCSELs do not emit light.

Note that the capacitors 70A, 70B are connected to the power supply 82 via the resistance element 72, the other terminal of the resistance element 72 has the power supply potential, and the other terminal connected to the reference line 84 has reference potential. Thus, the capacitors 70A, 70B receive a current flowing from the power supply 82 via the resistance element 72, and are (supplied with an electric charge) charged.

Subsequently, when the signal generated by the signal generating circuit 52 in the driver 50 becomes “H level”, the FET device 51 makes a transition from OFF state to ON state. Then, a closed loop is formed by the capacitors 70A, 70B, and the FET device 51 and the VCSELs connected in series, and the electric charges accumulated in the capacitors 70A, 70B are supplied to the FET device 51 and the VCSELs connected in series. That is, a drive current flows through the VCSELs, which emit light. The closed loop is a driving circuit to drive the light source 20.

When the signal generated by the signal generating circuit 52 in the driver 50 becomes “L level” again, the FET device 51 makes a transition from ON state to OFF state. Thus, the closed loop (driving circuit) formed by the capacitors 70A, 70B, and the FET device 51 and the VCSELs connected in series becomes an open loop, and no drive current flows through the VCSELs. Thus, the VCSELs stop emitting light. Then, discharged electric charge is supplied from the power supply 82 to the capacitors 70A, 70B via the resistance element 72, and the capacitors 70A, 70B are charged.

As described above, each time the signal output by the signal generating circuit 52 makes a transition to “H level” and “L level”, the FET device 51 repeats ON and OFF, and the VCSELs repeat emission of light and non-emission of light. The repeat of ON and OFF of the FET device 51 may be called switching.

Note that charge time (time constant) τ since transition of the FET device 51 from an ON state to an OFF state until the capacitors 70A, 70B are charged up to the power supply potential of the power supply 82 is represented by the following expression, where C is the capacitance value of the parallel circuit of the capacitors 70A, 70B, and R is the resistance value of the resistance element 72.

τ=RC (1)

Note that the charge time τ is set according to the minimum value of the light emission interval of pulsed light. Specifically, the charge time τ is set to be sufficiently smaller than the minimum value of the light emission interval of pulsed light. Specifically, the capacitance value C of the parallel circuit of the capacitors 70A, 70B and the resistance value R of the resistance element 72 are set according to the minimum value of the light emission interval of pulsed light. Note that the charge time τ is set to a time which allows the capacitors to be charged to 63.2% of the power supply voltage of the power supply 82, for example.

(Heat Dissipation Base 100)

FIG. 6A is a plan view of the heat dissipation base 100. FIG. 6B is a cross-sectional view taken along VIB-VIB of FIG. 6A. FIG. 6C is a cross-sectional view taken along VIC-VIC of FIG. 6A.

In FIG. 6A, let +X direction be the right direction of the paper surface, −X direction be the left direction of the paper surface, +Y direction be the upper direction of the paper surface, and −Y direction be the lower direction of the paper surface. Let Z direction be the direction (front direction of the paper surface) perpendicular to the X direction and the Y direction. For the heat dissipation base 100 described below, the front direction (+Z direction) of the paper surface is referred to as the front surface or front surface side, and the rear direction (−Z direction) of the paper surface is referred to as the rear surface or rear surface side. In the following, viewing each member from the front surface side transparently is referred to as an upper surface view. Note that in FIG. 6B, the right direction of the paper surface is +X direction, the rear direction of the paper surface is +Y direction, and the upper direction of the paper surface is +Z direction.

As illustrated in FIGS. 6A to 6C, the light source 20, the FET device 51, the capacitors 70A, 70B, and the resistance element 72 are provided on the front surface of the heat dissipation base 100. As illustrated in FIG. 6B, FIG. 6C, the light diffusion member 30 is provided on the retainer 60.

The heat dissipation base 100 is constituted by being provided with a wiring layer in which a wire composed of metal such as copper (Cu) foil is formed in an insulating base, such as aluminum nitride (AlN) with a thermal conductivity of 100 W/m·K or higher, for example. When an inorganic base is used as the heat dissipation base 100, the thickness may be at least 100 μm for the sake of intensity. When the thickness exceeds 500 μm, use of the heat dissipation base 100 is difficult due to its inductance, thus the thickness may be less than or equal to 500 μm. Note that the effective inductance of the current loop may be 200 μm or less. Specifically, when an inorganic base is used as the heat dissipation base 100, the thickness may be 100 μm or greater and 500 μm or less, or may be 100 μm or greater and 200 μm or less.

Also, when an organic base is used as the heat dissipation base 100, a high thermal conductivity material may be used, and, for example, a base with a thermal conductivity of 1 to 5 W/m·K may be used. For example, when the thickness is approximately 10 μm, a base with a thermal conductivity of 1 to 5 W/m·K can be used. In the case of an organic base, unlike the case of an inorganic base, a base with a thickness less than 100 μm may be used.

As illustrated in FIG. 6A, in an upper surface view, the light source 20 is rectangular, and the cathode electrode 214 is provided in an area where the light source 20 is enlarged. Part of the cathode electrode 214 extends in −Y direction. The FET device 51 is provided on the extended part of the cathode electrode 214, and the cathode electrode 214 and the drain [D] of the FET device 51 are connected. Specifically, the FET device 51 is connected in series to the light source 20 by the same cathode electrode, and drives the light source 20.

In addition, the gate [G] of the FET device 51 is connected to an electrode 220 for gate provided on the front surface side of the heat dissipation base 100. The source [S] of the FET device 51 is connected to ground electrode 222 provided on the front surface side of the heat dissipation base 100.

As illustrated in FIG. 6C, the electrode 220 for gate is connected to ground electrode 226 provided on the rear surface side of the heat dissipation base 100 through conductive via-hole 224 which penetrates the heat dissipation base 100. In addition, the ground electrode 222 is connected to ground electrode 238 provided on the rear surface side of the heat dissipation base 100 through conductive via-hole 230 which penetrates the heat dissipation base 100.

In addition, on the front surface side of the heat dissipation base 100, the anode electrode 218 is provided to surround three sides: the right side (+X side), the left side (−X side), and the upper side (+Y side) of the light source 20 in FIG. 6A. The right side (+X side) and the left side (−X side) of the light source 20 are connected to the anode electrode 218 by wire bonding using wires 232.

The left side (−X side) of the light source 20 is provided with the capacitor 70A. One terminal of the capacitor 70A is connected to the anode electrode 218, and the other terminal is connected to ground electrode 234. As illustrated in FIG. 6B, the ground electrode 234 is connected to the ground electrode 238 provided on the rear surface side of the heat dissipation base 100 through conductive via-hole 236 which penetrates the heat dissipation base 100. The right side (+X side) of the light source 20 is provided with the capacitor 70B. One terminal of the capacitor 70B is connected to the anode electrode 218, and the other terminal is connected to ground electrode 240. As illustrated in FIG. 6B, the ground electrode 240 is connected to the ground electrode 238 provided on the rear surface side of the heat dissipation base 100 through conductive via-hole 242 which penetrates the heat dissipation base 100.

As illustrated in FIG. 6A, the resistance element 72 is provided on the upper side of the capacitor 70B. One terminal of the resistance element 72 is connected to the anode electrode 218, and the other terminal is connected to power supply electrode 244. The power supply electrode 244 is connected to the power supply 82.

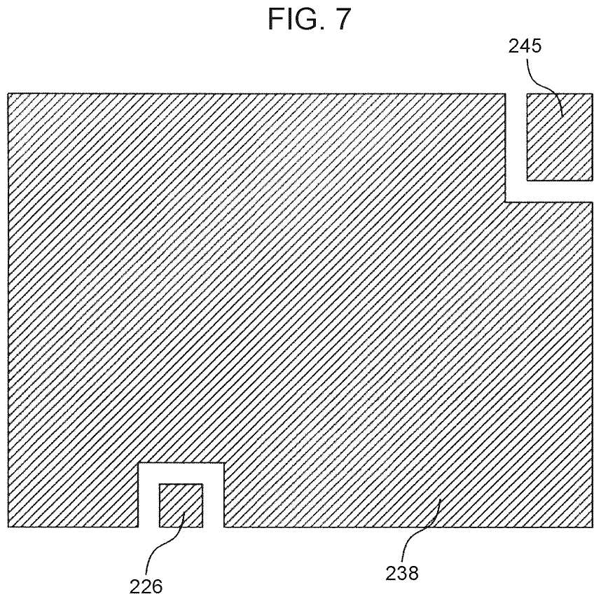

FIG. 7 is an upper surface view of the ground electrodes 226, 238, 245 provided on the rear surface side of the heat dissipation base 100. As illustrated in FIG. 7, substantially the entire surface of the rear surface side of the heat dissipation base 100 is provided with the ground electrodes. Thus, the drive current that causes the light source 20 to emit light flows from the anode electrode 218 to the cathode electrode 214 along a current path on the heat dissipation base 100, and a current also flows through a path in which the current path is projected onto the ground electrode 238 on the rear surface side of the heat dissipation base 100. In addition, the drain and the source of the FET device 51 are directly connected on the heat dissipation base 100, thus the effective inductance of the current path is minimized. Thus, a pulse with a short pulse width can be risen fast by a high current value with a low power supply voltage. At the same time, the cathode electrode 214 and the ground electrode 238 which are connected to the light source 20 are opposed on the front side and the rear side of the heat dissipation base 100 having a high thermal conductivity, thus the heat generated by the light source 20 is efficiently dissipated to the ground electrode 238.

Although the exemplary embodiment has been described above, the technical scope of the present disclosure is not limited to the scope described in the exemplary embodiment. Various modifications or improvements can be made to the exemplary embodiment in a range not departing from the gist of the disclosure, and embodiments to which the modifications or improvements are made are also included in the technical scope of the present disclosure.

The exemplary embodiment is not intended to limit the disclosure according to the claims, and all the combinations of the features described in the exemplary embodiment are not necessarily essential to the solution of the disclosure. The exemplary embodiment described above includes the disclosure at various stages, and various aspects of the disclosure are provided by combining multiple claim components disclosed. As long as an effect is obtained even with some claim components removed from all claim components shown in the exemplary embodiment, the configuration with some claim components removed can be provided as the disclosure.

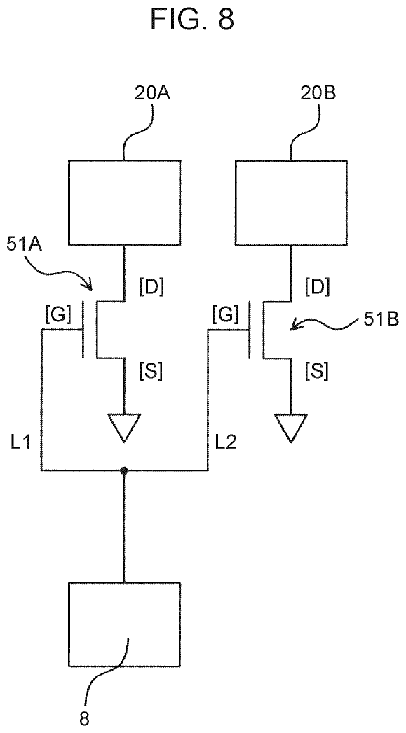

For example, in this exemplary embodiment, a case has been described in which the light source 20 and the FET device 51 are provided one each; however, multiple pairs of the light source 20 and the FET device 51 may be provided. In this case, from the controller 8 that outputs a control signal to control a plurality of FET devices, signal wires to the plurality of FET devices may branch with equal length. For example, as illustrated in FIG. 8, when a configuration is adopted in which two light sources 20A, 20B, and two FET devices 51A, 51B are provided, signal wires from the controller 8 to the gates of the FET devices 51A, 51B branch with equal length so that distance L1 from the controller 8 to the gate of the FET device 51A, and distance L2 from the controller 8 to the gate of the FET device 51B are equal. In addition, the same cathode electrode 214 connected to the cathodes of the light sources 20A, may be provided on the heat dissipation base 100.

The present application claims priority based on Japanese Patent Application No. 2021-047642 filed in Japan on Mar. 22, 2021.

The foregoing description of the exemplary embodiments of the present disclosure has been provided for the purposes of illustration and description. It is not intended to be exhaustive or to limit the disclosure to the precise forms disclosed. Obviously, many modifications and variations will be apparent to practitioners skilled in the art. The embodiments were chosen and described in order to best explain the principles of the disclosure and its practical applications, thereby enabling others skilled in the art to understand the disclosure for various embodiments and with the various modifications as are suited to the particular use contemplated. It is intended that the scope of the disclosure be defined by the following claims and their equivalents.

What is claimed is:

1. A light emitting device comprising:
a light emitting element;
a switch element that is connected in series to one of electrodes of the light emitting element, and that drives the light emitting element;
a capacitive element that is connected in parallel to the light emitting element, and that discharges a charged electric charge to the light emitting element; and
a resistance element provided between the capacitive element and a power supply that charges the capacitive element
on a same base.

2. The light emitting device according to claim 1,
wherein an electrostatic capacitance value of the capacitive element and a resistance value of the resistance element are determined according to a minimum value of a light emission interval of pulsed light emitted from the light emitting element.

3. The light emitting device according to claim 1,
wherein the base is aluminum nitride.

4. The light emitting device according to claim 2,
wherein the base is aluminum nitride.

5. The light emitting device according to claim 1,
wherein the base is an inorganic base with a thickness of 100 μm or greater and 500 μm or less and a thermal conductivity of 100 W/m·K or higher.

6. The light emitting device according to claim 2,
wherein the base is an inorganic base with a thickness of 100 μm or greater and 500 μm or less and a thermal conductivity of 100 W/m·K or higher.

7. The light emitting device according to claim 3,
wherein the base is an inorganic base with a thickness of 100 μm or greater and 500 μm or less and a thermal conductivity of 100 W/m·K or higher.

8. The light emitting device according to claim 4,
wherein the base is an inorganic base with a thickness of 100 μm or greater and 500 μm or less and a thermal conductivity of 100 W/m·K or higher.

9. The light emitting device according to claim 1,
wherein the base is an organic base with a thickness less than 100 μm and a thermal conductivity of 1 W/m·K or higher.

10. The light emitting device according to claim 2,
wherein the base is an organic base with a thickness less than 100 μm and a thermal conductivity of 1 W/m·K or higher.

11. The light emitting device according to claim 1,
wherein a plurality of pairs of the light emitting element and the switch element are provided.

12. The light emitting device according to claim 2,
wherein a plurality of pairs of the light emitting element and the switch element are provided.

13. The light emitting device according to claim 3,
wherein a plurality of pairs of the light emitting element and the switch element are provided.

14. The light emitting device according to claim 4,
wherein a plurality of pairs of the light emitting element and the switch element are provided.

15. The light emitting device according to claim 5,
wherein a plurality of pairs of the light emitting element and the switch element are provided.

16. The light emitting device according to claim 6,
wherein a plurality of pairs of the light emitting element and the switch element are provided.

17. The light emitting device according to claim 7,
wherein a plurality of pairs of the light emitting element and the switch element are provided.

18. The light emitting device according to claim 11,
wherein signal wires with equal length branch from a controller to a plurality of switch elements, each of which is the switch element, the controller being configured to output a control signal to control the plurality of switch elements.

19. The light emitting device according to claim 11,
wherein a same cathode electrode to be connected to cathodes of a plurality of light emitting elements, each of which is the light emitting element, is provided on the base.

20. A measuring device comprising:
the light emitting device according to claim 1;
a light receiving element that receives reflected light of light emitted from the light emitting device to a to-be-measured object; and
a measurer that measures a distance to the to-be-measured object by a time-of-flight as an indirect method based on an amount of light received by the light receiving element.
